(19) United States
(12) Patent Application Publication
(10) Pub. No.: US 2020/0256904 A1
(43) Pub. Date: Aug. 13, 2020

(54) Systems and Methods for Active Testing of Electrostatic Grounding

(71) Applicant: UI LABS, Chicago, IL (US)

(72) Inventors: Antonio Del Sesto, Chicago, IL (US); Paul L. Pierson, Evanston, IL (US)

(73) Assignee: UI LABS, Chicago, IL (US)

(21) Appl. No.: 16/273,652

(22) Filed: Feb. 12, 2019

(51) Int. Cl. G01R 27/18; G01R 31/02

(52) U.S. Cl. CPC G01R 27/18; G01R 31/024

(57) ABSTRACT

Systems and methods are provided for electrostatic discharge (ESD) testing at manufacturing or repair workspaces. An operator's connection to ground is tested periodically, with the test being initiated by an action at the workspace, such as the operating touching equipment at the workspace, or an operation being completed at the workspace. A logic unit is triggered to query ESD test results upon the occurrence of such an action. The test is automatically completed and test results are provided.

### BACKGROUND OF THE INVENTION

Electrostatic discharge (ESD) is a common phenomenon that results when two objects of differing electrical charge come into contact or close proximity and electricity quickly flows between the two objects.

While electrostatic discharge in day-to-day life is relatively harmless, there are instances where ESD can cause significant damage. One example of a case where ESD can cause problems is in the production, repair, and use of electronics. Electrostatic discharge can result in complete failure of electronics and their components, or may result in smaller flaws that are not readily apparent.

For this reason, preventing electrostatic discharge during manufacture or repair of electronics is important. This is often accomplished with the use of a grounding strap, such as at the wrist or heel, that creates an electrical connection between a person (such as a manufacturer, operator, or repairperson) and the ground. Maintaining this grounding connection preferably keeps the person at the same electric potential as the piece he or she is working on, thereby maintaining a low risk of ESD.

It is important that this grounding connection is not merely maintained, but is also actively verified to be maintained. Systems and methods for active testing of grounding for the prevention of ESD will be of benefit.

### FIELD OF THE INVENTION

The invention pertains to the field of grounding testing. More particularly, the invention pertains to active testing of grounding for the prevention of electrostatic discharge.

### SUMMARY OF THE INVENTION

A system tests the grounding status of an operator who is using equipment. The system comprises a grounding connection between the operator and a known electrical ground, a tester configured to test the resistance of the grounding connection and a logic unit configured to trigger the tester. The logic unit queries the tester when the operator is making physical contact with the equipment. The logic unit may query the tester in response to an action initiated at the work station.

### BRIEF DESCRIPTION OF THE DRAWINGS

FIG. 1 shows an operator using manufacturing equipment according to one embodiment of the present invention;

FIG. 2 shows a block diagram of a grounding testing system according to one embodiment of the present invention;

FIG. 3 shows a more detailed block diagram demonstrating the operation of a grounding testing system according to one embodiment of the present invention; and

FIG. 4 shows a flow diagram illustrating the operation of a logic unit according to one embodiment of the invention.

### DETAILED DESCRIPTION OF THE INVENTION

Systems and methods according to the present invention use active testing systems to confirm the grounding status of operators in electronics manufacturing and repair environments.

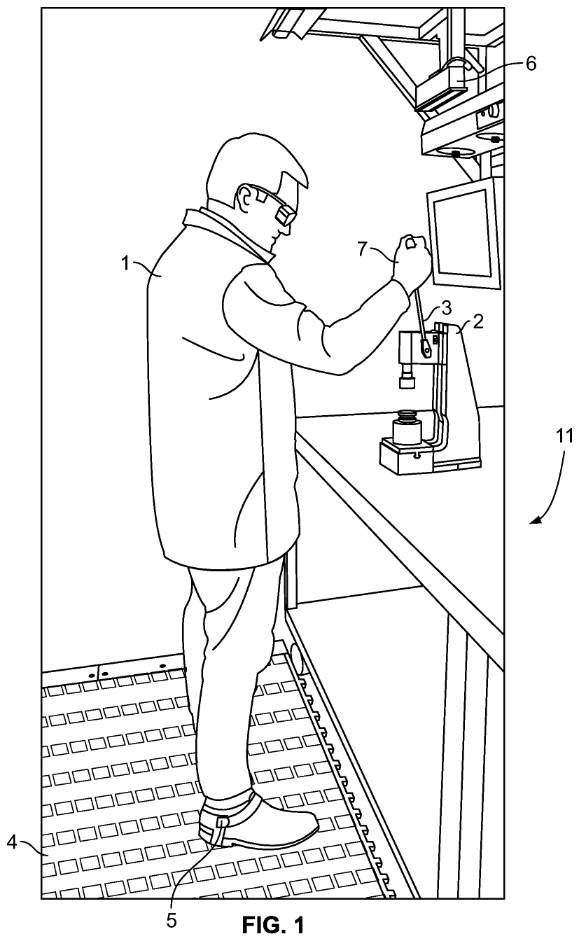

FIG. 1 is an illustration showing an operator 1 at a work station using a piece of equipment 2. In this case, the piece of equipment is a Schmidt press having a handle 3. The part contained in the equipment 2 is sensitive to ESD. The operator is standing on a grounded, conductive floor mat 4 and is wearing a foot ground strap 5. Through the use of a sensor (such as a switch that can detect the position of the handle 3) provided in the equipment, or a spatial sensor 6, it can be determined when the equipment 2 is in operation and, thus, when the operator 1's hand 7 is in contact with the handle 3 (which is conductive).

In embodiments of this invention, explained in greater detail below, this information about the operator 1's conductive contact with the equipment 2 can be used to cause a logic unit (not shown in FIG. 1) to query an ESD tester (not shown in FIG. 1) at a time when the operator's hand 7 is touching the handle 3. The ESD tester uses the contact of the operator's hand 7 to the handle 3 as a test point to check the ground status of the operator 1. The area including the equipment 2 and the grounding mat 4 may be termed a work station 11.

Ground conductivity (or resistance) testing may be termed “ESD testing.” The goal of ESD testing is to confirm a low-resistance connection between operators and ground, thereby confirming that electrical charge, which might damage sensitive equipment or workpieces, is not building in the operator. ESD testing can be conducted regularly during use of the equipment, for example every time the operator 1 pulls the handle 3. Therefore, ESD testing is performed during the manufacturing or repair process, and potentially on every operation of the equipment 2. The testing is some embodiments is performed without any separate test action being taken by the operator 1, and either with or without the operator 1 being informed of the status of the test.

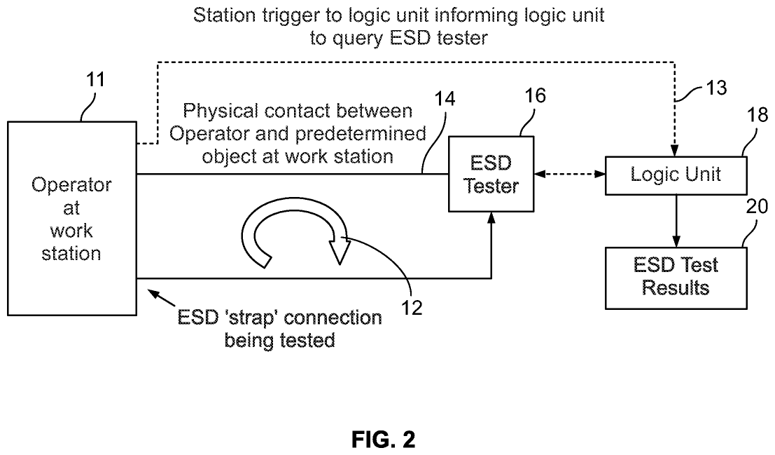

FIG. 2 is a block diagram showing the operation of one embodiment of the present invention. An operator 1 testing for ESD, positioned at a work station 11, is part of a circuit 12 that is created when the operator makes contact with a predetermined object at the work station (as shown by line 14). An ESD tester 16 is placed within this circuit 12, and has components within it that test the resistance (or conductance) within the circuit 12. A variety of types of ESD testers may be used in the present invention, including ESD testers with digital outputs or ESD testers with LED outputs that can be used with a translator (coupler) that can convert the LED status to a digital signal. ESD testers with relay outputs that trigger depending on pass or fail of a test may also be used.

An ESD connection (such as the strap connection 5 as shown in FIG. 1) is tested by the ESD tester. In the illustrated example, the ESD connection is depicted as a ‘strap’ connection, but it is to be understood that the ESD connection may take the form of ESD shoes, wrist or heel straps, ground-connected clothing, or any other conductive connection to ground.

A logic unit 18 may be triggered by a signal 13, such as a trigger signal, sent from the work station 11. This signal may be provided via a simple wire with a high or low signal provided on it, though other signal types such as optical coupling or wireless signaling may be used. Upon receipt of this signal, the logic unit 18 queries the ESD tester 16 to find the grounding status of the operator 1. ESD test results may be provided as shown at block 20. The test results may be given via an auditory signal or via a visual signal. In some embodiments, the test results, if indicating a failure of the ESD connection, may cause a shutdown of the work station 11.

Test results may be used for alerts, shutdowns, data gathering for trend analysis, tracking grounding for individual operators, and other purposes. Time stamps of a failures may be tied to potential product quality issues. For example, if there is an operator 1 with a record of a higher than normal number of failures, that operator's grounding equipment can be evaluated and, if needed, repaired or replaced.

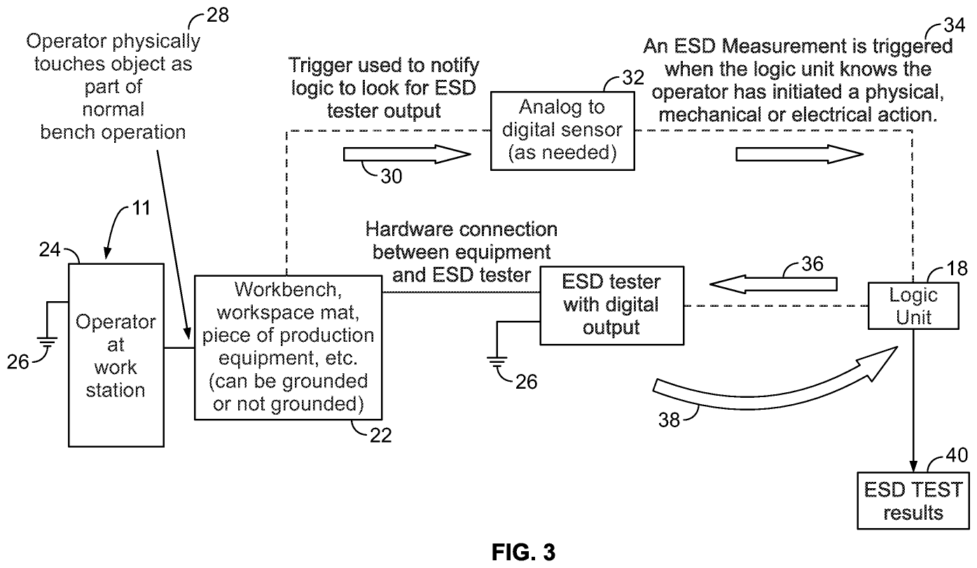

FIG. 3 shows the operation of one embodiment of the present invention. In this embodiment, an operator is positioned in front of a piece of equipment at a work station 11. The operator is standing on an ESD mat 4 that is connected to ground as shown by the ground symbol 26, and a foot strap provides a conductive connection between the operator 1 and the ESD mat 4 (as shown in FIG. 1). As shown at block 28, the operator 1 physically touches an object 22 as part of normal bench operation. This touching operation may result in a trigger signal as indicated at arrow 30 that may pass to an optional analog-to-digital sensor 32. Alternatively, another method may be used as a trigger while the touching operation is done.

Several different occurrences at the work station 11 could give rise to the trigger signal. For example, a step in a manufacturing or repair process at the work station 11 may give rise to the trigger signal. In one example, if the operator 1 pulls a metal handle on a press, if the metal is grounded, the trigger signal 30 can be sent from the work station 11. A mechanical switch or special sensor may be used to generate the signal 30, and the signal 30 may be generated by a programmable logic controller (PLC) on the equipment at the work station 11. The trigger signal 30 serves as a sign from the work station 11 that the operator 1 is known to be touching a grounded portion of the equipment at the work station 11, and thus that a grounding test can be usefully performed at the time that the trigger signal 30 is sent. Thus an action initiated at the work station 11 indicates readiness for testing. In some cases, the action is initiated by the operator 1, and in some cases the action is initiated by the equipment.

As shown at 34, the trigger signal is transmitted to a logic unit 18. The logic unit 18, in turn, queries (as shown by arrow 36) an ESD tester 16. In some embodiments, the logic unit 18 may send a querying signal to the ESD tester, but in others the logic unit 18 merely receives the grounding test results from the ESD tester. In the embodiment shown in FIG. 3, the ESD tester 16 has a digital output. The ESD tester checks the grounding connection between the operator 1 and ground, and provides a result signal to the logic unit 18, as shown by arrow 38. If the resistance (or conductivity) of the operator's ground connection is within an acceptable range, the ESD tester provides a pass signal to the logic unit 18. If the resistance (or conductivity) of the operator's ground connection is not within an acceptable range, the ESD tester provides a fail signal to the logic unit 18.

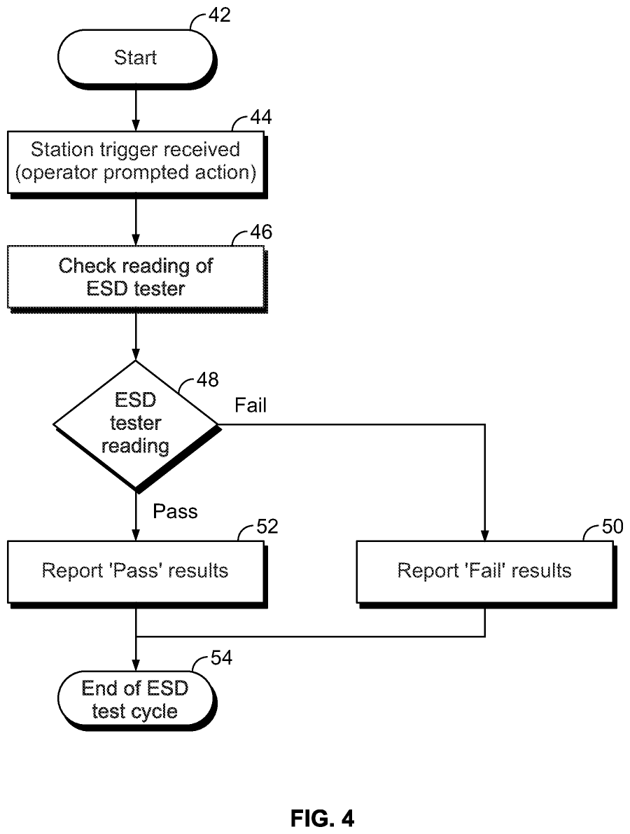

FIG. 4 is a flow chart showing the operation of the logic unit 18. Block 42 shows the start of an ESD testing process according to one embodiment of the present invention. As shown at block 44, a station trigger signal is received by the logic unit, with this trigger signal being generated by an operator's action or another action taken during the process at the work station 11 showing that the operator 1 is touching a grounded portion of the work station.

After receipt of the trigger signal 44, the logic unit checks the reading of the ESD tester as shown at block 46, which represents a grounding status test result. As shown by decision block 48, if the ESD tester reading shows a fail of the grounding connection, fail results are signaled and/or recorded as indicated at block 50. If the ESD tester reading shows a pass of the grounding connection, pass results are signaled and/or recorded as indicated at block 52. The reporting and/or recording of the pass or fail results then bring the process to the end block 54. As noted above, actions taken due to a fail result may include alerts, shutdowns, data gathering for trend analysis, tracking failures for individual operators, and other purposes. Time stamps of a failures may be tied to potential product quality issues. These actions may be initiated by the logic unit 18, or by other electronic units (such as computers or digital storage units such as storage drives) or human actors.

Turning back to FIG. 3, ESD test results may be signaled as shown at block 40. The test results may be given via an auditory signal and/or via a visual signal. In some embodiments, the test results, if indicating a failure of the ESD connection, may cause a shutdown of the work station 11.

In some embodiments of the present invention, a grounding testing system is provided as a built-in feature of manufacturing or repair equipment. Systems and methods according to the present invention can be accomplished using separate pieces of hardware, or a unitary piece of hardware, as befits any specific application of the invention.

ESD test results may be logged in a record and time-stamped for later checking. According to embodiments of the present invention, real-time ESD verification can be achieved at workplaces. The operator's connection to ground is preferably tested during operation activities, and this testing does not require the operator to move away from the machine, or to engage in any specific testing action, for ESD testing to be completed. Thus, operation time is increased and disruptions for testing are diminished. Further, faults can be discovered almost immediately so that damage to workpieces or equipment is diminished.

The methods and systems disclosed herein may make use of software, or computer code that constitutes a computer program, that is stored in memory on a device such as the logic unit 18. That software may in some embodiments be considered firmware as discussed herein. Firmware is, generally, a computer program that is stored in a non-volatile memory on a device. This means that the computer program may be effectively fixed in the device's storage, with the possibility of changing or updating such firmware. The computer code may be, though will not always be, installed in memory at the time of manufacture of the memory itself thereby reducing risks associated with tampering that may occur at the time of installation.

In general, a computer program in accordance with the embodiments described herein may include a computer usable storage medium (e.g., standard random access memory (RAM), a universal serial bus (USB) drive, or the like) having computer-readable program code embodied therein, wherein the computer-readable program code may be adapted to be executed by a processor, such as processor(s) within the logic unit 18, to facilitate the functions as described herein. In this regard, the program code may be implemented in any desired language, and may be implemented as machine code, assembly code, byte code, interpretable source code or the like (e.g., via C, C++, Java, Actionscript, Objective-C, Javascript, CSS, XML).

Although the preceding text sets forth a detailed description of numerous different embodiments, it should be understood that the legal scope of the invention may be defined by the words of the claims set forth at the end of this patent. The detailed description is to be construed as exemplary only and does not describe every possible embodiment, as describing every possible embodiment would be impractical, if not impossible. One could implement numerous alternate embodiments, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Additionally, certain embodiments are described herein as including logic or a number of routines, subroutines, applications, or instructions. These may constitute either software (e.g., code embodied on a non-transitory, machine-readable medium) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that may be permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that may be temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired), or temporarily configured (e.g., programmed) to operate in a certain manner or to perform certain operations described herein. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules may provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses) that connect the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it may be communicatively coupled. A further hardware module may then, at a later time, access the memory device to retrieve and process the stored output. Hardware modules may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some example embodiments, the processor or processors may be located in a single location (e.g., within a home environment, an office environment, or as a server farm), while in other embodiments the processors may be distributed across a number of locations.

In some embodiments, the performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A system for testing the grounding status of an operator interacting with equipment at a work station, said system comprising:
a grounding connection between the operator and a known electrical ground;
a tester configured to test the resistance of the grounding connection; and
a logic unit configured to query the tester when the operator is making physical contact with the equipment, said logic unit querying the tester in response to an action initiated at the work station.

2. The system of claim 1 wherein the action is initiated by the equipment.

3. The system of claim 2 wherein the action is initiated by a switch provided on the equipment.

4. The system of claim 1 wherein the action initiated at the work station is sensed by a spatial sensor, which sends a trigger signal to the logic unit.

5. The system of claim 1 wherein the action initiated at the work station results in the sending of trigger signal to the logic unit.

6. The system of claim 1 wherein the logic unit receives a grounding status test result from the tester and stores the grounding status test result.

7. The system of claim 1 wherein the logic unit creates a test result signal that is used to provide an alert indicating the results of the grounding test.

8. A method for testing the grounding status of an operator interacting with equipment at a work station, said method comprising:
providing a grounding connection between the operator and a known electrical ground;
providing a tester configured to test the resistance of the grounding connection, said tester generating grounding status test results;
providing a logic unit configured to query the tester and process the grounding test results; and
querying the tester via said logic unit when the operator is making physical contact with the equipment, said querying occurring in response to an action initiated at the work station.

9. The method of claim 8 comprising the equipment initiating the action.

10. The method of claim 9 wherein the action is initiated by a switch provided on the equipment.

11. The method of claim 8 further comprising providing a spatial sensor and sending a trigger signal to the logic unit via said spatial sensor.

12. The method of claim 8 wherein the action initiated at the work station results in the sending of trigger signal to the logic unit.

13. The method of claim 8 further comprising receiving a grounding status test result from the tester at the logic unit and stores the grounding status test result at the logic unit.

14. The method of claim 13 further comprising creating at the logic a test result signal that is used to provide an alert indicating the results of the grounding test.

15. A system for testing the grounding status of an operator interacting with equipment at a work station, said system comprising:
a grounding connection between the operator and a known electrical ground;
a tester configured to test the resistance of the grounding connection;
a logic unit configured to query the tester when the operator is making physical contact with the equipment; and
means for generating and sending a trigger signal from said work station to said logic unit in response to an action initiated at the work station.

16. The system of claim 16 wherein the means of generating and sending a trigger signal comprises a mechanical switch or sensor on the equipment at the work station.

17. The system of claim 16 wherein the means of generating and sending a trigger signal comprises a special signal at or near the work station.

18. The system of claim 16 wherein the logic unit is further configured to generate a pass or fail signal, with a pass signal being generated if the tester indicates a pass when queried by the logic unit and a fail signal being generated if the tester indicates a fail when queried by the logic unit.

19. The system of claim 18 further comprising means for recording said pass or fail signal.

20. The system of claim 19 wherein said means for recording said pass or fail signal is a digital storage unit.
